(19) United States
(12) Patent Application Publication
(10) Pub. No.: US 2026/0223444 A1
(43) Pub. Date: Jul. 30, 2026

(54) HIGH-VOLTAGE DEVICES WITH EXTENDED TAP ACTIVE AREAS

(71) Applicant: Micron Technology, Inc., Boise, ID (US)

(72) Inventors: Michael A. Smith, Boise, ID (US); Sanchar Acharya, Hyderabad (IN)

(21) Appl. No.: 19/411,098

(22) Filed: Dec. 5, 2025

Related U.S. Application Data
(60) Provisional application No. 63/750,981, filed on Jan. 29, 2025.

(51) Int. Cl. H10D 84/83; H10D 30/63; H10D 62/10; H10D 62/60

(52) U.S. Cl. CPC H10D 84/83138; H10D 30/637; H10D 62/102; H10D 62/124; H10D 62/60

(57) ABSTRACT

High-voltage semiconductor devices with extended active areas (and associated systems, devices, and methods) are disclosed herein. In one embodiment, a high-voltage semiconductor device includes a high-voltage N-well formed in a substrate. The high-voltage N-well includes a mask edge corresponding to a location of an N-well junction formed in the substrate. The device further includes (i) an active area and (ii) a local deep trench isolation region positioned within the substrate and laterally adjacent to the high-voltage N-well. The active area can extend beyond the mask edge of the high-voltage N-well such that a region of the active area is positioned between the mask edge of the high-voltage N-well and the local deep trench isolation region. The extended active area is expected to improve breakdown voltage characteristics of the device when using local deep trench isolation.

### CROSS-REFERENCE TO RELATED APPLICATION(S

The present application claims priority to U.S. Provisional Patent Application No. 63/750,981, filed January 29, 2025, the disclosure of which is incorporated herein by reference in its entirety.

### TECHNICAL FIELD

This disclosure relates generally to semiconductor devices. For example, several embodiments of the present technology described in detail below are directed to high-voltage (HV) semiconductor devices with improved breakdown voltage characteristics using extended tap active areas with local deep trench isolation.

### BACKGROUND

High-voltage semiconductor devices are widely used in various applications, including power management, automotive electronics, and industrial control systems. As semiconductor technology continues to advance, there is a growing demand for high-voltage devices with improved performance characteristics, such as smaller footprints and/or smaller spacings between adjacent devices or components.

One challenge in designing high-voltage semiconductor devices is managing the electric field distribution within the device structure. Proper control of the electric field is crucial for maintaining high breakdown voltages while also maintaining other desirable device characteristics. To this end, isolation structures play a critical role in high-voltage semiconductor devices, as they help prevent unwanted interactions between adjacent components and contribute to overall device performance.

Shallow trench isolation (STI) has been widely adopted in semiconductor manufacturing due to its ability to provide effective electrical isolation while allowing for higher device density. As device scaling continues and/or voltage requirements increase, however, traditional STI may not always provide sufficient isolation for high-voltage applications. Local deep trench (LDT) isolation is one option that looks promising for improving isolation capabilities in high-voltage semiconductor devices. The integration of LDT with existing high-voltage device architectures, however, presents new challenges that must be addressed to fully realize its potential benefits.

### BRIEF DESCRIPTION OF FIGURES

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1A illustrates a partially schematic, top orthogonal view of an integrated high-voltage (HV) switch.

FIG. 1B depicts a cross-sectional view of dopant profiles in a portion of the integrated HV switch of FIG. 1A.

FIG. 2 illustrates a cross-sectional view of dopant profiles in two high-voltage semiconductor devices arranged adjacent one another and separated by LDT isolation regions.

FIG. 3 illustrates a partially schematic, top orthogonal view of a high-voltage (HV) semiconductor device configured in accordance with various embodiments of the present technology.

FIG. 4 illustrates another partially schematic, top orthogonal view of the HV semiconductor device of FIG. 3.

FIGS. 5A-5E are cross-sectional views of dopant profiles in two high-voltage semiconductor devices arranged adjacent one another, each view illustrating a different example spacing between an LDT isolation region and an N-well mask edge in accordance with various embodiments of the present technology.

FIG. 6 illustrates a partially schematic, top orthogonal view of an example semiconductor layout with adjacent high-voltage semiconductor devices, the example semiconductor layer configured in accordance with various embodiments of the present technology.

### DETAILED DESCRIPTION

The present technology relates generally to improving (e.g., decreasing) spacing between high-voltage semiconductor devices and adjacent components. For example, several embodiments of the present technology described in detail below are directed to improving spacing between integrated high-voltage switches using local deep trench isolation regions and extended tap active areas. Integrated high-voltage switches, however, are merely used as an example of the present technology. Stated another way, the present technology is not limited to integrated high-voltage switches. Indeed, aspects and principles of the present technology described herein can be utilized in other high-voltage devices that incorporate high-voltage N-well structures.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element’s or feature’s relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

### A. Overview

Many high-voltage semiconductor devices utilize shallow trench isolation (STI) to provide electrical isolation between adjacent components. While STI has been widely adopted due to its ability to enable higher device density, it may not always provide sufficient isolation for high-voltage applications as device scaling continues and voltage requirements increase. Thus, the inventors of the present technology have identified local deep trench (LDT) isolation as a promising technique for improving isolation capabilities in high-voltage semiconductor devices such that spacing between a high-voltage semiconductor device and an adjacent component can be reduced.

The integration of LDT isolation with existing high-voltage device architectures, however, presents new challenges. For example, the inventors have discovered that many high-voltage devices experience a reduction in breakdown voltage when LDT isolation regions are introduced near high-voltage N-well regions. Without being bound by theory, the inventors have attributed this unexpected behavior to the intersection of the N-well/N- junction with sidewalls of the LDT isolation regions, which can create undesirable electric field distributions. As a result, without further modification, the potential benefits of LDT techniques in terms of improved isolation and reduced device spacing may be offset by compromised breakdown voltage characteristics.

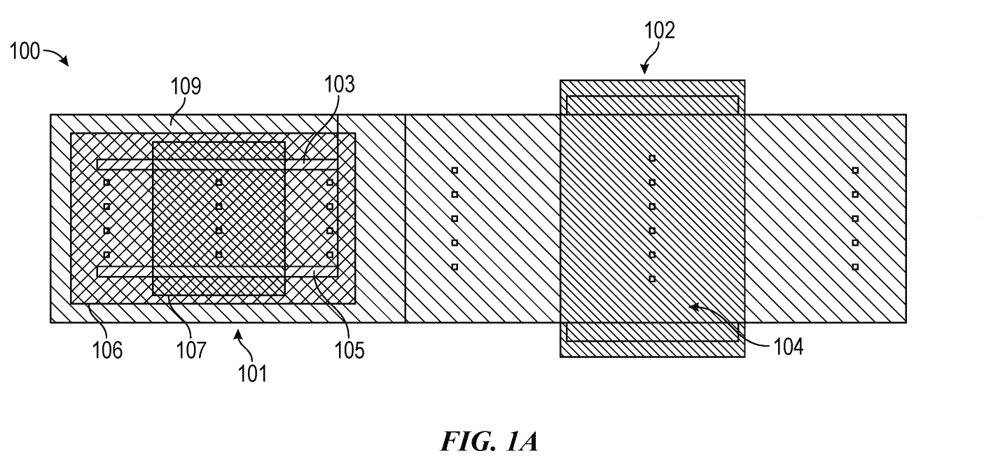

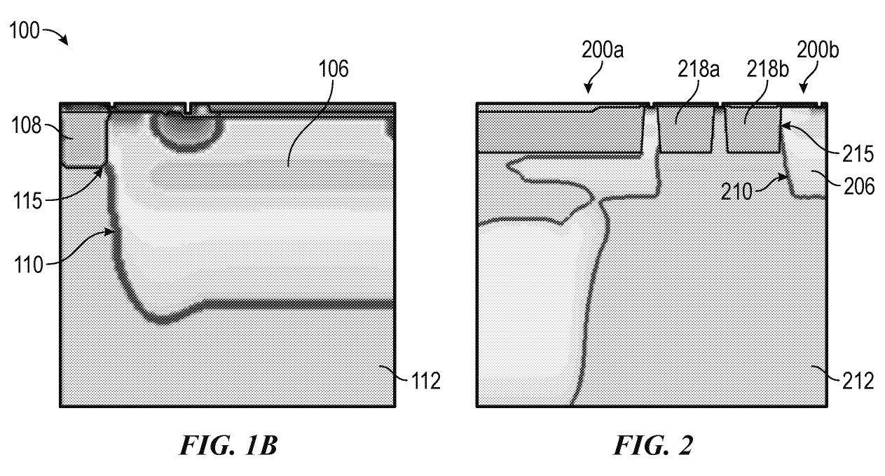

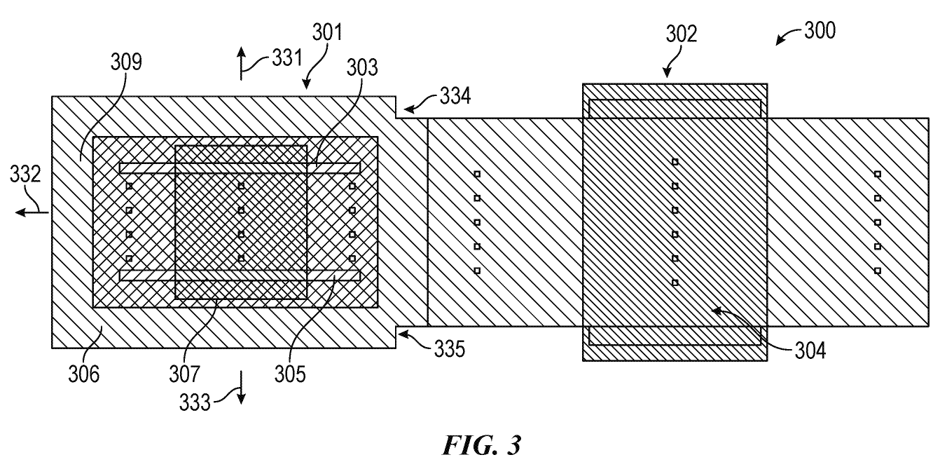

For the sake of clarity and understanding of the discussion above, consider FIGS. 1A-2. FIG. 1A illustrates a partially schematic, top orthogonal view of an integrated high-voltage (HV) switch 100. As shown, the integrated HV switch 100 includes a high-voltage p-type (HVP) field effect transistor 101 and a high-voltage depletion (HVD) transistor 102. In the illustrated embodiment, the integrated HV switch 100 further includes (i) a continuous tap active area 109 that is generally rectangular in shape and extends across the HVP field effect transistor 101 and the HVD transistor 102, and (ii) a high-voltage N-well 106 formed in the active area 109. Edges of the active area 109 are not shown aligned with the boundary of the high-voltage N-well 106 merely for the sake of illustration to depict diffusion that can occur (e.g., as a result of process thermal cycling). Otherwise, the edges of the active area 109 can be aligned with the edges of the high-voltage N-well 106. The HVP field effect transistor 101 is illustrated in FIG. 1A with a first trench 103, a second trench 105, and a gate 107. The first and second trenches 103 and 105 can be used to define edges of the HVP field effect transistor 101 (e.g., used to define channel width of the HVP field effect transistor 101). A gate 104 of the HVD transistor 102 is also shown in FIG. 1A.

FIG. 1B depicts a cross-sectional view of dopant profiles in a portion of the integrated HV switch 100 of FIG. 1A. More specifically, FIG. 1B illustrates an STI region 108 positioned adjacent the high-voltage N-well 106 of FIG. 1A. A mask edge 110 (corresponding to a boundary of the N-well 106 and a boundary of an N- implant) is shown in FIG. 1B that visually identifies the location of an N-well/N- junction that is formed within substrate 112 after (or as a result of) process thermal cycling. As shown, the N-well/N- junction intersects the STI region 108 at location 115, corresponding to a bottom corner of the STI region 108. Such an arrangement results in little to no noticeable reduction in breakdown voltage. That said, use of an STI region 108 (as opposed to an LDT isolation region) limits how closely spaced a high-voltage N-well structure can be positioned relative to an adjacent component before electrical isolation is compromised.

The inventors have discovered, however, that simply swapping out the STI region 108 for an LDT isolation region can result in an undesirable reduction in breakdown voltage. For example, FIG. 2 illustrates a cross-sectional view of a first high-voltage device 200a and a second high-voltage device 200b that are arranged adjacent one another and separated by first and second LDT isolation regions 218a and 218b, respectively. As shown, the second high-voltage device 200b includes a high-voltage N-well 206 formed in a tap active area of a substrate 212. A mask edge 210 (corresponding to a boundary of the N-well 206 and a boundary of an N- implant) is shown in FIG. 2 that visually identifies the location of an N-well/N- junction that is formed within substrate 212 after (or as a result of) process thermal cycling. As shown, the N-well/N- junction intersects the STI region 108 at location 215, corresponding to a position along a sidewall of the LDT isolation region 218. As discussed above and without being bound by theory, the inventors believe that such an arrangement contributes to a realized reduction in breakdown voltage for the second high-voltage device 200b.

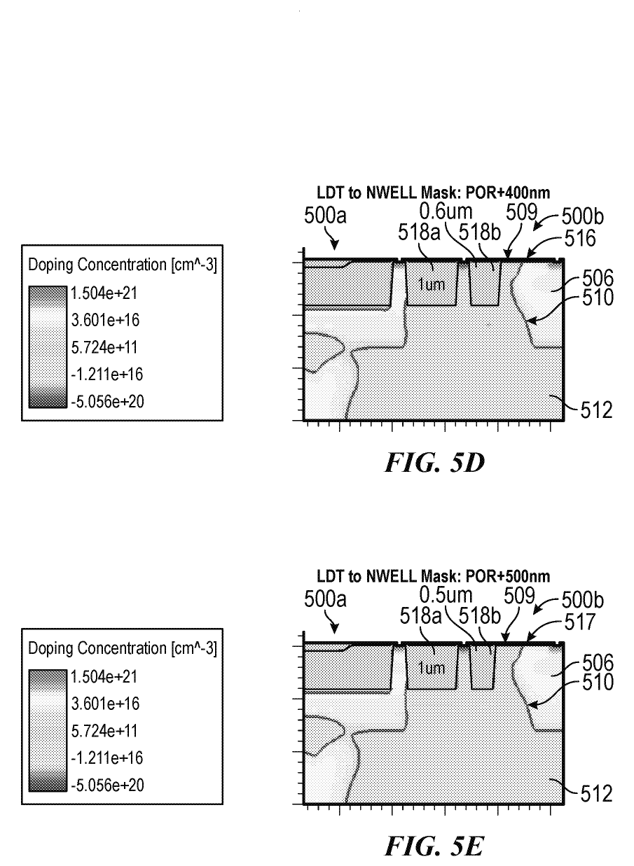

To address these challenges and concerns, the inventors have developed high-voltage semiconductor devices with extended tap active areas that enable use of LDT isolation regions such that spacing between high-voltage N-well structures and adjacent components can be reduced to levels not achievable when employing STI regions. For example, in various embodiments of the present technology, an integrated high-voltage switch includes a high-voltage p-type field effect transistor, a high-voltage depletion transistor, and a continuous tap active area that extends across both transistors. A high-voltage N-well is formed in the active area, and a local deep trench isolation region is positioned laterally adjacent to the high-voltage N-well. The tap active area is extended beyond a mask edge of the high-voltage N-well such that an N-well/N- junction formed within a substrate intersects a surface of the substrate rather than a sidewall of the local deep trench isolation region (as shown in FIGS. 5A-5E and described in greater detail below).

Such a configuration is expected to provide several advantages over other designs. For example, by extending the tap active area beyond the N-well mask edge, the N-well/N- junction is shifted away from the sidewall of the local deep trench isolation region. This arrangement helps maintain a high breakdown voltage while still benefiting from the improved isolation capabilities of local deep trench structures. As a result, spacing between adjacent high-voltage devices or components can be reduced without compromising electrical performance. In other words, the extended tap active area is expected to effectively mitigate the unexpected reduction in breakdown voltage that was observed by the inventors when replacing shallow trench isolation with local deep trench isolation in high-voltage device architectures.

Furthermore, embodiments of the present technology offer flexibility in design and manufacturing. For example, the extent to which the tap active area is extended beyond the N-well mask edge can be optimized to achieve desired breakdown voltage characteristics while minimizing overall device footprint. Additionally, in some embodiments, the N- implant mask can be adjusted independently of the N-well mask to further fine-tune device performance. These features allow for the development of high-voltage semiconductor devices with improved isolation, reduced spacing requirements, and maintained or enhanced breakdown voltage characteristics, addressing the challenges associated with device scaling and increasing voltage requirements in modern semiconductor applications.

### B.Selected Embodiments of High-Voltage Devices with Extended Tap Active Areas, and Associated Systems, Devices, and Methods

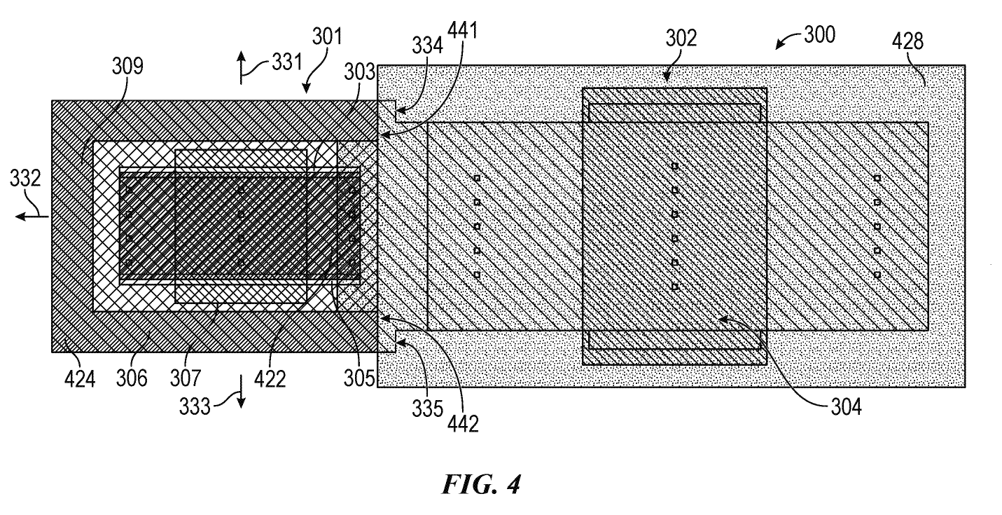

FIG. 3 illustrates a partially schematic, top orthogonal view of a high-voltage semiconductor device 300 configured in accordance with various embodiments of the present technology. For the sake of example, the high-voltage semiconductor device 300 is configured as an integrated high-voltage (HV) switch that is generally similar to the integrated HV switch 100 described above with reference to FIG. 1A. Thus, similar reference numbers are used across FIGS. 1A and 3 to denote generally similar components. For example, as shown in FIG. 3, the high-voltage semiconductor device 300 of FIG. 3 includes a high-voltage p-type (HVP) field effect transistor 301 and a high-voltage depletion (HVD) transistor 302. The HVP field effect transistor 301 includes a first trench 303, a second trench 305, and a gate 307. The first and second trenches 303 and 305 can be used to define edges of the HVP field effect transistor 301 (e.g., used to define channel width of the HVP field effect transistor 301). In addition, the HVD transistor 302 is shown with a gate 304.

The high-voltage semiconductor device 300 of FIG. 3 further includes a high-voltage N-well 306 formed in a tap active area 309. Similar to the tap active area 109 of the integrated HV switch 100 of FIG. 1A, the tap active area 309 of the high-voltage semiconductor device 300 of FIG. 3 can be a continuous region, such as a region that extends across both the HVP field effect transistor 301 and the HVD transistor 302. In contrast with the active area 109 of FIG. 1A, however, the active area 309 of FIG. 3 is extended beyond mask edges of the high-voltage N-well 306. More specifically, in comparison with the active area 109 of FIG. 1A, the active area 309 of FIG. 3 has been extended beyond mask edges of the high-voltage N-well 306 along three sides of the high-voltage N-well 306 (e.g., (generally along arrows 331-333). As discussed in greater detail below, extending the continuous tap active area 309 can include providing a larger active area, pulling back various mask edges (e.g., a mask edge of the high-voltage N-well 306 and/or a mask edge of an N- implant), and/or reducing a width of a local deep trench (LDT) isolation region (not shown) positioned laterally adjacent the high-voltage N-well 306.

As a result of the continuous tap active area 309 being extended, the continuous tap active area 309 can include a non-rectangular shape. For example, the active area 309 can include (i) a first width along portions of the active area 309 that correspond to the HVD transistor 302 and (ii) a second, wider width along portions of the active area 309 that correspond to the high-voltage N-well 306 and/or the HVP field effect transistor 301. Thus, in some embodiments, the active area 309 can include one or more step-out areas 334 and 335 attributable to extension of the tap active area 309 generally along one or more of the arrows 331-333.

The extended active area 309 is expected to provide several advantages. For example, the extended active area 309 is expected to help maintain a high breakdown voltage of the high-voltage semiconductor device 300 while enabling use of local deep trench (LDT) isolation structures. In turn, use of LDT isolation structures is expected to enable reduced spacing between adjacent high-voltage devices or components without compromising electrical performance.

It should be noted that while the high-voltage semiconductor device 300 is illustrated as an integrated HV switch in FIG. 3 as an example, the aspects and principles of the present technology may be applied to high-voltage N-wells generally, not just integrated high-voltage switches. For example, the extended active area concept described above and in greater detail below may be utilized in various high-voltage semiconductor devices that incorporate high-voltage N-well structures to achieve similar benefits in terms of breakdown voltage and device spacing. In at least some of these high-voltage semiconductor devices, the active area can be extended beyond mask edges of a high-voltage N-well on any number of sides of the high-voltage N-well. For example, in the case of a generally rectangular high-voltage N-well structure, the active area can be extended beyond mask edges of the high-voltage N-well on one, two, three, or all four sides of the high-voltage N-well structure. More generally, an active area can be extended beyond mask edges of a high-voltage N-well structure on all or a subset of the sides of the high-voltage N-well structure.

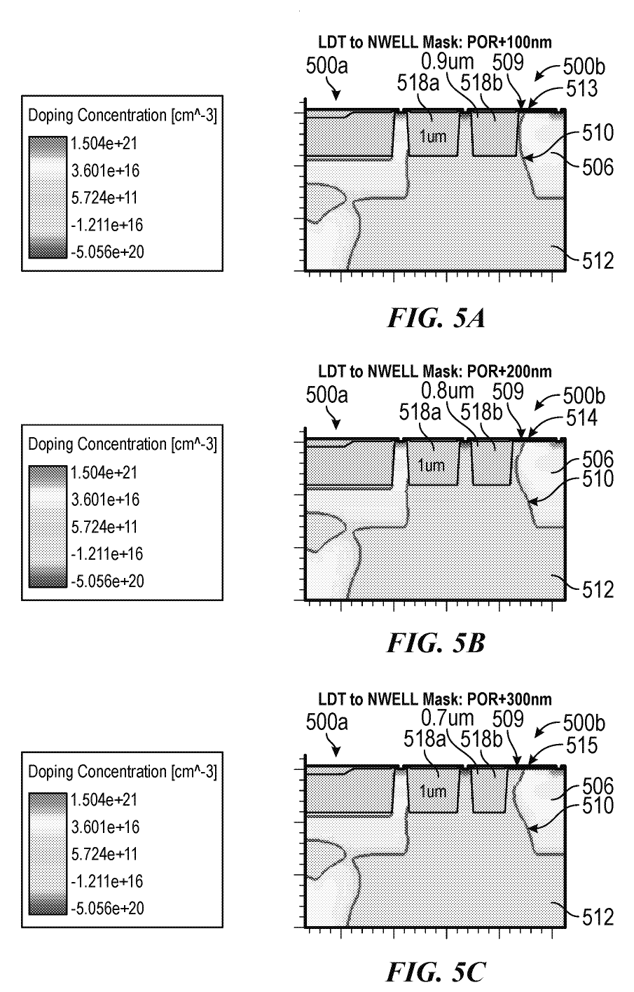

FIG. 4 illustrates another partially schematic, top orthogonal view of the high-voltage semiconductor device 300 of FIG. 3. More specifically, FIG. 4 illustrates the high-voltage semiconductor device 300 with various regions 422, 424, and 428 overlayed thereon. Region 422 corresponds to a portion of the high-voltage semiconductor device 300 that are not exposed to an N- implant, region 424 corresponds to a portion of the of the high-voltage semiconductor device 300 that may or may not be exposed to an N- implant, and region 428 corresponds to a portion of the high-voltage semiconductor device 300 that may be exposed to an N+ implant.

More specifically, as discussed above, the active area 309 of the high-voltage semiconductor device 300 extends beyond mask edges of the high-voltage N-well 306 on three sides of the high-voltage N-well 306. This extension can result in a non-rectangular shape for the active area 309, including a step-out area 334 and a step-out area 335. Region 422 and the step-out areas 334 and 335 can generally correspond to portions of the active area 309 that extend beyond mask edges of the high-voltage N-well 306.

In some embodiments, mask edges of the high-voltage N-well 306 can generally correspond to mask edges of an N- implant. In these embodiments, the region 422 shown in FIG. 4 may correspond to a portion of the active area 309 that extends beyond both the mask edge of the high-voltage N-well 306 and a mask edge of an N-minus implant. Stated another way, a portion of the high-voltage semiconductor device 300 shown positioned between the region 422 and the region 424 in FIG. 4 can be exposed to an N- implant, while the portions of the high-voltage semiconductor device 300 corresponding to the regions 422 and 424 can be generally devoid of the N- implant. For example, the N- implant may be omitted from the extended portions of the active area 309 around the high-voltage N-well 306.

In other embodiments, positions of one or more mask edges of the high-voltage N-well 306 can differ from positions of one or more mask edges of an N- implant. In at least some of these embodiments, all or a subset of the region 422 can be exposed to an N- implant. For example, a portion of the high-voltage semiconductor device 300 shown positioned between the region 422 and the region 424 in FIG. 4 can be exposed to an N- implant. In addition, all or a subset of the region 424 can be exposed to the N- implant such that mask edges of the N- implant can extend beyond mask edges of the high-voltage N-well 306. As a specific example, the N- implant may be included in a portion of the region 424 corresponding to the extended portions of the active area 309 but be pulled back from the edge of the active area 309. For example, the N-minus implant may be present in a portion of the region 424 but not extend to the edge of the extended active area 309.

As discussed above, the region 428 can correspond to a portion of the high-voltage semiconductor device 300 that is exposed to an N+ implant. As shown in FIG. 4, the region 428 can include a recessed (or cutaway) portion 441 and/or a recessed (or cutaway) portion 442. For example, in embodiments that include N- implant in all or a subset of the region 424, the region 428 can include the recessed portion 441 and/or the recessed portion 442 to accommodate the N- implant in the region 424.

FIGS. 5A-5E are cross-sectional views of dopant profiles in two high-voltage semiconductor devices 500a and 500b that are arranged adjacent one another and that are configured in accordance with various embodiments of the present technology. More specifically, as shown in each of FIGS. 5A-5E, a first high-voltage (HV) semiconductor device 500a is arranged laterally adjacent to a second high-voltage (HV) semiconductor device 500b. The first high-voltage (HV) semiconductor device 500a and the second high-voltage (HV) semiconductor device 500b are separated by a first local deep trench isolation region 518a and a second local deep trench isolation region 518b, respectively. In some embodiments, the first high-voltage semiconductor device 500a and/or the second high-voltage semiconductor device 500b can be configured as an integrated high-voltage switch (e.g., similar to the integrated high-voltage switch described in detail above with reference to FIGS. 3 and 4, or another integrated high-voltage switch configured in accordance with various embodiments of the present technology).

Each view provided by FIGS. 5A-5E illustrates a different example spacing between the second LDT isolation region 518b and a mask edge 510 of a high-voltage N-well 506 of the semiconductor device 500b. The spacings are referred to herein as "LDT-to-N-well spacings." Referring first to FIG. 5A, a high-voltage N-well 506 is formed in a tap active area 509 of a substrate 512. In the illustrated example, the active area 509 extends a distance beyond a mask edge 510 of the high-voltage N-well 506 (which may or may not also correspond to a mask edge of an N- implant). As such, a portion of the active area 509 is shown positioned between the mask edge 510 of the high-voltage N-well 506 and a sidewall of the LDT isolation region 518b. As a result, rather than intersecting the sidewall of the LDT isolation region 518b, the N-well junction (as well as the N- junction when the mask edge 510 also corresponds to a mask edge of the N- implant) intersects the silicon (or a surface) of the substrate at location 513. In some embodiments, the example LDT-to-N-well spacing shown in FIG. 5A can be approximately 100nm.

FIGS. 5B-5E each illustrates an example of a larger LDT-to-N-well spacing. For example, the example LDT-to-N-well spacing shown in FIG. 5B can correspond to approximately 200nm, the example LDT-to-N-well spacing shown in FIG. 5C can correspond to approximately 300nm, the example LDT-to-N-well spacing shown in FIG. 5D can correspond to approximately 400nm, and the example LDT-to-N-well spacing shown in FIG. 5E can correspond to approximately 500nm. As shown in FIGS. 5A-5E, larger LDT-to-N-well spacings can correspond to (a) larger extensions of the tap active area 509 beyond the mask edge 510 of the high-voltage N-well 506 and/or the N-implant, and/or (b) to thinner thicknesses of the second LDT isolation region 518b. As shown, locations 513-517 at which the N-well junction and/or N- junction intersect the silicon (or the surface) of the substrate 512 can stay relatively constant and independent of LDT-to-N-well spacing.

Each of the examples illustrated in FIGS. 5A-5E are expected to realize an improvement in breakdown voltage over embodiments in which the N-well junction and/or the N- junction intersect a sidewall of the second LDT region 218b. Without being bound by theory, this improvement may be attributed to a reduction in electric field crowding at the intersection of the N-well/N- junction and the sidewall of the first local deep trench isolation region 518a. That said, it is expected that there is an upper limit for the LDT-to-N-well spacing beyond which deep sub-surface punch-through leakage will be observed between the first and second high-volage semiconductor devices 500a and 500b. Therefore, the LDT-to-N-well spacing can be optimized to maintain or improve breakdown voltage of the second high-voltage semiconductor device 500b while avoiding deep sub-surface punch-through leakage between the second high-voltage semiconductor device 500b and the first high-voltage semiconductor device 500a. In some embodiments, the LDT-to-N-well spacing can be optimized based on other device requirements and/or design constraints, such as overall footprint of the second high-voltage semiconductor device 500b.

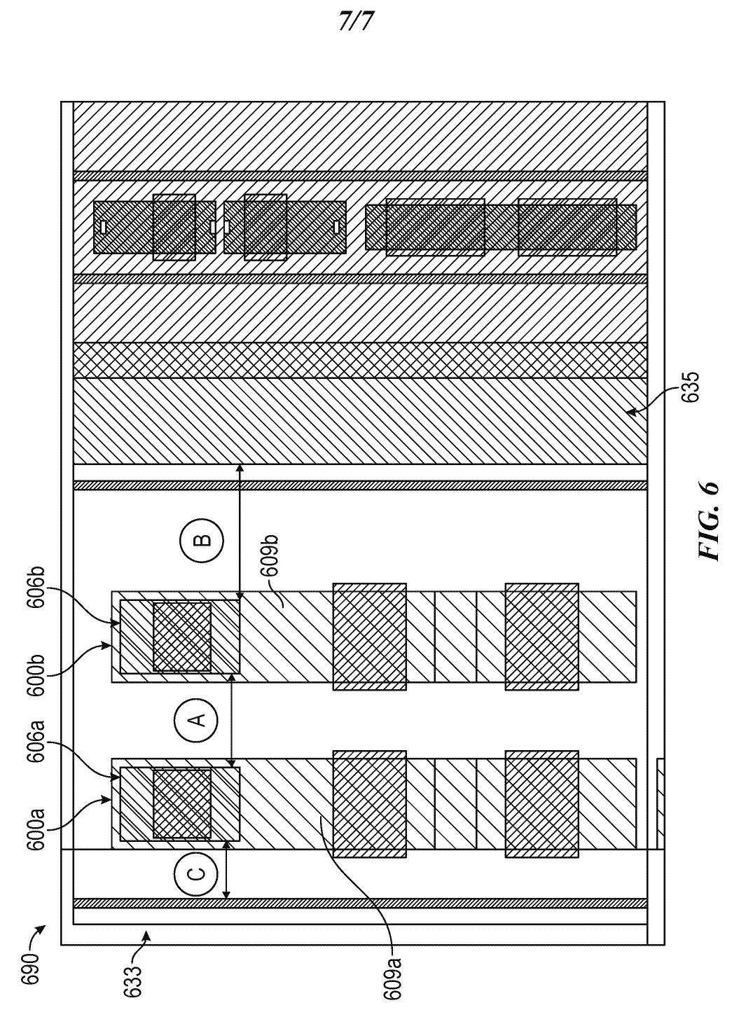

FIG. 6 illustrates a partially schematic, top orthogonal view of a semiconductor layout 690 configured in accordance with various embodiments of the present technology. As shown, the semiconductor layout 690 includes a first high-voltage (HV) semiconductor device 600a and a second high-voltage (HV) semiconductor device 600b arranged adjacent to one another. In some embodiments, the first high-voltage (HV) semiconductor device 600a and/or the second high-voltage (HV) semiconductor device 600b may be configured as an integrated high-voltage switches similar to the integrated high-voltage switch described above with reference to FIGS. 3, 4 and/or 5.

The first high-voltage semiconductor device 600a includes a first high-voltage N-well 606a, and the second high-voltage semiconductor device 600b includes a second high-voltage N-well 606b. As discussed above with reference to FIGS. 5A-5E, the first and second high voltage N-wells 606a and 606b can be isolated from one another using one or more LDT isolation regions (not shown in FIG. 6). As a result, a first spacing distance A can be reduced in comparison to an arrangement in which the high-voltage N-wells 606a and 606b are isolated from one another using STI regions, such as from approximately 3µm to about 2.25µm. As discussed above, extension of tap active areas 609a and 609b beyond corresponding mask edges of the first and second high-voltage N-wells 606a and 606b, respectively, can avoid reduction in breakdown voltages of the first and second high-voltage semiconductor devices 600a and 600b, respectively, when using such LDT isolation regions.

The semiconductor layout 690 is further illustrated with a triple well (or deep n-well) region 635. In some embodiments, the triple well region 635 can include a low-voltage N-well along its boundary, such as an N-well biased to V_{CC} or some other low volage value. Additionally, or alternatively, the semiconductor layout 690 can include a region 633 including an N-well for low-voltage circuitry. In these embodiments, the first high-voltage N-well 606a of the first high-voltage semiconductor device 600a can be isolated from the N-well of region 633 using an LDT isolation region (not shown), and/or the second high-voltage N-well 606b of the second high-voltage semiconductor device 600b can be isolated from the low-voltage N-well of the triple well region 635 using an LDT isolation region (not shown). As a result, a second spacing distance B and/or a third spacing difference C can be reduced in comparison to an arrangement in which the high-voltage N-wells 606a and 606b are isolated from the N-well(s) of the regions 633 and/or 635 using STI regions, such as from approximately 3.25µm to about 2.5µm. As discussed above, extension of tap active areas 609a and 609b beyond corresponding mask edges of the first and second high-voltage N-wells 606a and 606b, respectively, can avoid reduction in breakdown voltages of the first and second high-voltage semiconductor devices 600a and 600b, respectively, when using such LDT isolation regions.

The reduced spacing between components of the semiconductor layout 690 that can be achieved using aspects and principles of the present technology may allow for higher device density and/or improved integration of high-voltage semiconductor devices with low-voltage components on the same semiconductor substrate.

The present technology is also directed to various methods of forming one or more high-voltage semiconductor devices. Such methods can include forming a high-voltage N-well, such as in a substrate; forming an active area (e.g., a tap active area) that extends beyond a mask edge of the high-voltage N-well; and/or forming a local deep trench isolation region laterally adjacent to the high-voltage N-well. Forming the high-voltage N-well can include forming an N-well junction within the substrate that intersects silicon or a surface of the substrate, such as without interesting a sidewall or another portion of the local deep trench isolation region. Forming the active area can include extending the active area beyond the mask edge of the high-voltage N-well on one or more sides (e.g., one, two, three, or more) of the high-voltage N-well, such as on at least three sides of the high-voltage N-well.

One or more of these methods can further include forming an N- implant region. Forming the N- implant region can include forming the N- implant region such that a mask edge of the N- implant region is aligned with the mask edge of the high-voltage N-well. Alternatively, forming the N- implant region can include forming the N- implant region such that a mask edge of the N- implant region extends beyond the mask edge of the high-voltage N-well and/or is at least partially positioned between the local deep trench isolation region and the mask edge of the high-voltage N-well.

In some embodiments, forming the one or more high-voltage semiconductor devices can include forming one or more integrated high-voltage switches. Forming the one or more integrated high-voltage switches can include an integrated high-voltage switch having a high-voltage p-type field effect transistor and/or a high-voltage depletion transistor. In at least some of these embodiments, forming the active area can include forming a tap active area that includes a continuous region that extends across both (i) a high-voltage p-type field effect transistor and (ii) a high-voltage depletion transistor.

### C.Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A high-voltage semiconductor device, comprising:
a high-voltage N-well formed in a substrate, the high-voltage N-well having a mask edge corresponding to a location of an N-well junction formed in the substrate;
a local deep trench isolation region positioned within the substrate and laterally adjacent to the high-voltage N-well; and
an active area extending beyond the mask edge of the high-voltage N-well such that a region of the active area is positioned between the mask edge of the high-voltage N-well and the local deep trench isolation region.

2. The high-voltage semiconductor device of claim 1, wherein the active area extends beyond the mask edge of the high-voltage N-well such that the N-well junction intersects a surface of the substrate.

3. The high-voltage semiconductor device of claim 1, wherein the active area extends beyond the mask edge of the high-voltage N-well such that the mask edge of the high-voltage N-well does not intersect the local deep trench isolation region.

4. The high-voltage semiconductor device of claim 1, wherein the active area extends beyond the mask edge of the high-voltage N-well such that the mask edge of the high-voltage N-well does not intersect a sidewall of the local deep trench isolation region.

5. The high-voltage semiconductor device of claim 1, wherein the active area extends beyond the mask edge of the high-voltage N-well on at least three sides of the high-voltage N-well.

6. The high-voltage semiconductor device of claim 1, wherein the active area has a non-rectangular shape.

7. The high-voltage semiconductor device of claim 6, wherein the active area includes:
a first region having a first width;
a second region integral with the first region and having a second width larger than the first width; and
at least one step-out area corresponding to a transition from the first width to the second width.

8. The high-voltage semiconductor device of claim 1, further comprising an N- implant region, wherein a mask edge of the N- implant region is aligned with the mask edge of the high-voltage N-well.

9. The high-voltage semiconductor device of claim 1, further comprising an N- implant region, wherein a mask edge of the N- implant region extends beyond the mask edge of the high-voltage N-well such that an N- junction corresponding to the N- implant intersects the local deep trench isolation region.

10. The high-voltage semiconductor device of claim 1, further comprising an N- implant region, wherein a mask edge of the N- implant region extends beyond the mask edge of the high-voltage N-well such that an N- junction corresponding to the N- implant (i) does not intersect the local deep trench isolation region and (ii) is positioned between the local deep trench isolation region and the mask edge of the high-voltage N-well.

11. The high-voltage semiconductor device of claim 1, wherein the high-voltage semiconductor device is an integrated high-voltage switch comprising a high-voltage p-type field effect transistor and a high-voltage depletion transistor.

12. The high-voltage semiconductor device of claim 11, wherein the active area is a continuous region that extends across both the high-voltage p-type field effect transistor and the high-voltage depletion transistor.

13. A semiconductor layout, comprising:
a first high-voltage semiconductor device comprising a first high-voltage N-well;
a second high-voltage semiconductor device comprising a second high-voltage N-well, the second high-voltage semiconductor device positioned laterally adjacent to the first high-voltage semiconductor device; and
a local deep trench isolation region positioned between the first high-voltage N-well and the second high-voltage N-well, wherein at least one of the first high-voltage semiconductor device or the second high-voltage semiconductor device comprises an active area that extends beyond a mask edge of its respective high-voltage N-well such that a region of the active area is positioned between the mask edge and the local deep trench isolation region.

14. The semiconductor layout of claim 13, wherein the active area extends beyond the mask edge of the high-voltage N-well such that an N-well junction corresponding to the respective high-voltage N-well does not intersect the local deep trench isolation region.

15. The semiconductor layout of claim 13, wherein the active area extends beyond the mask edge of its respective high-voltage N-well on at least three sides of the high-voltage N-well.

16. The semiconductor layout of claim 13, wherein at least one of the first high-voltage semiconductor device or the second high-voltage semiconductor device further comprises an N- implant region, and wherein a mask edge of the N- implant region is aligned with the mask edge of its respective high-voltage N-well.

17. The semiconductor layout of claim 13, wherein at least one of the first high-voltage semiconductor device or the second high-voltage semiconductor device further comprises an N- implant region, and wherein a mask edge of the N- implant region extends beyond the mask edge of its respective high-voltage N-well such that the mask edge of the N- implant region is positioned between the local deep trench isolation region and the mask edge of the respective high-voltage N-well.

18. The semiconductor layout of claim 13, wherein:
at least one of the first high-voltage semiconductor device or the second high-voltage semiconductor device is an integrated high-voltage switch comprising a high-voltage p-type field effect transistor and a high-voltage depletion transistor; and
the active area is a tap active area including a continuous region that extends across both the high-voltage p-type field effect transistor and the high-voltage depletion transistor.

19. An integrated high-voltage switch, comprising:
a high-voltage p-type field effect transistor formed at least in part using a high-voltage N-well;
a high-voltage depletion transistor positioned on a first side of the high-voltage N-well;
a tap active area having a continuous region that extends across both the high-voltage p-type field effect transistor and the high-voltage depletion transistor; and
a local deep trench isolation region positioned on a second side of the high-voltage N-well different from the first side, wherein the tap active area extends beyond a mask edge of the high-voltage N-well at the second side of the high-voltage N-well such that a region of the tap active area is positioned between the mask edge of the high-voltage N-well and the local deep trench isolation region.

20. The integrated high-voltage switch of claim 19, wherein:
the local deep trench isolation region is a first local deep trench isolation region;
the integrated high-voltage switch further comprises a second local deep trench isolation region positioned on a third side of the high-voltage N-well different from the first and second sides;
the mask edge is a first mask edge;
the region of the tap active area is a first region; and
the tap active area extends beyond a second mask edge of the high-voltage N-well at the third side of the high-voltage N-well such that a second region of the tap active area is positioned between the second mask edge of the high-voltage N-well and the second local deep trench isolation region.
